(19) United States
(12) Patent Application Publication
(10) Pub. No.: US 2008/0292029 A1
(43) Pub. Date: Nov. 27, 2008

(54) Method and Apparatus For Carrier Recovery Using Multiple Sources

(75) Inventor: Joshua Lawrence Koslov, Hopewell, NJ (US)

Correspondence Address: Joseph J. Laks;Thomson Licensing LLC, 2 Independence Way, Patent Operations, PO Box 5312, PRINCETON, NJ, 08543, US

(73) Assignee: THOMSON LICENSING, Boulogne (FR)

(21) Appl. No.: 11/667,791

(22) PCT Filed: Nov. 16, 2004
(86) PCT No.: PCT/US04/38654

§ 371 Date: May 15, 2007

(51) Int. Cl. H03D 1/00

(52) U.S. Cl. 375/341

(57) ABSTRACT

A receiver comprises a multiple source phase estimator. The latter comprises a pilot-phase estimator, a data-driven average phase estimator, a selector and a common interpolation controller. The selector selects either the pilot-phase estimator or the data-driven average phase estimator as the source of determined phase estimates at particular times. At other times, the common interpolation controller provides interpolated phase estimates as a function of a linear interpolation based on a respective determined phase estimate.

### BACKGROUND OF THE INVENTION

The present invention generally relates to communications systems and, more particularly, to carrier recovery.

A carrier recovery loop, or carrier tracking loop, is a typical component of a communications system. The carrier recovery loop is a form of phase locked loop (PLL) and, in general, takes the form of a “Costas Loop.” The latter typically uses a decision-directed phase error estimator to drive the PLL. In a decision-directed phase error estimator, the loop is driven by phase errors between received signal points and respective sliced symbols (nearest symbols) taken from a symbol constellation. In other words, for each received signal point a hard decision is made as to which is the closest (and presumably correct) symbol (also referred to as the sliced symbol) of the symbol constellation. From this hard decision, the phase error between the received signal point and the associated sliced symbol is then used to drive the PLL. When the carrier frequency offset, i.e., the frequency difference between the carrier of the received signal and the recovered carrier, is outside the “lock range” of the loop, the so-called “pull-in” process occurs, in which, under proper operating conditions, the loop operates to reduce the carrier frequency offset until the carrier frequency offset falls inside the lock range of the loop and phase lock follows.

However, as the signal-to-noise ratio (SNR) drops the above-mentioned phase error estimate approach of the Costas loop becomes increasingly unreliable because the hard decision process begins to make more and more wrong decisions as to the received symbols. As such, other methods of estimating the phase are preferable. For example, in a system with known pilot symbols, a corresponding receiver includes a pilot-based phase interpolator so that the phase may be reliably determined at the pilot times and linearly interpolated in between the pilot times. Conversely, in a system lacking pilot symbols, a receiver includes a data-driven interpolator such that the phase estimate may also be determined periodically by using a data-driven average, such as represented by the Viterbi and Viterbi algorithm (A. J. Viterbi and A. M. Viterbi, “Nonlinear estimation of PSK-modulated carrier phase with application to burst digital transmission,” IEEE Transactions on Information Theory, vol. IT-29, pp. 543-551, July, 1983). Again, in this data-driven process linear interpolation is used to estimate the phase at other times.

### SUMMARY OF THE INVENTION

I have observed that it is beneficial for a receiver to be able to incorporate both a pilot-based phase estimator and a non-pilot-based phase estimator. For example, this provides the ability to select between a pilot-based interpolating process with the non-pilot-based phase interpolating process. Therefore, and in accordance with the principles of the invention, a receiver includes a pilot-based phase estimator, a non-pilot-based phase estimator and a selector for selecting between the pilot-based phase estimator and the non-pilot-based phase estimator for use in performing carrier recovery on a received signal.

In an embodiment of the invention, a receiver comprises a multiple source phase estimator. The latter comprises a pilot-phase estimator, a data-driven average phase estimator, a selector and a common interpolation controller. The selector selects either the pilot-phase estimator or the data-driven average phase estimator as the source of determined phase estimates at particular times. At other times, the common interpolation controller provides interpolated phase estimates as a function of a linear interpolation based on a respective determined phase estimate.

In accordance with a feature of the invention, the use of a common interpolation controller minimizes any additional circuitry and/or processing in the receiver.

In another embodiment of the invention, a receiver comprises a multiple source phase estimator. The latter comprises a pilot-phase estimator, a data-driven average phase estimator, a selector, a Costas loop and a common interpolation controller. The selector selects either the pilot-phase estimator or the data-driven average phase estimator as the source of determined phase estimates at particular times. At other times, the common interpolation controller provides interpolated phase estimates as a function of a linear interpolation based on a respective determined phase estimate and at least one decision-directed phase error estimate from the Costas loop.

### BRIEF DESCRIPTION OF THE DRAWINGS

FIG. 1 shows a portion of an illustrative communications system embodying the principles of the invention;

FIG. 2 shows in illustrative format of a received signal;

FIG. 3 shows an illustrative embodiment of a receiver in accordance with the principles of the invention;

FIG. 4 shows an illustrative embodiment of a demodulator in accordance with the principles of the invention;

FIG. 5 shows an illustrative embodiment of a multiple source phase estimator in accordance with the principles of the invention;

FIG. 6 illustrates an EPOCH for use in the multiple source phase estimator of FIG. 5;

FIG. 7 shows another illustrative embodiment of a multiple source phase estimator in accordance with the principles of the invention;

FIG. 8 shows an illustrative flow chart in accordance with the principles of the invention;

FIGS. 9 and 10 illustrative phase excursion examples;

FIG. 11 illustrates another embodiment in accordance with the principles of the invention;

FIG. 12 shows an illustrative embodiment of a decision-directed carrier recovery element used to assist in carrier recovery in accordance with the principles of the invention;

FIG. 13 illustrates a phase excursion calculator for use in the embodiment of FIG. 11;

FIG. 14 shows an illustrative flow chart in accordance with the principles of the invention; and

FIG. 15 illustrates another embodiment in accordance with the principles of the invention.

### DETAILED DESCRIPTION

Other than the inventive concept, the elements shown in the figures are well known and will not be described in detail. Also, familiarity with satellite-based systems is assumed and is not described in detail herein. For example, other than the inventive concept, satellite transponders, downlink signals, symbol constellations, carrier recovery, interpolation, phase-locked loops (PLLs), a radio-frequency (rf) front-end, or receiver section, such as a low noise block downconverter, formatting and encoding methods (such as Moving Picture Expert Group (MPEG)- 2 Systems Standard (ISO/IEC 13818-1)) for generating transport bit streams and decoding methods such as log-likelihood ratios, soft-input-soft-output (SISO) decoders, Viterbi decoders are well-known and not described herein. In addition, the inventive concept may be implemented using conventional programming techniques, which, as such, will not be described herein. Finally, like-numbers on the figures represent similar elements and some of the figures simplify the processing representation. For example, those skilled in the art appreciate that carrier recovery involves processing in the real and the complex domains.

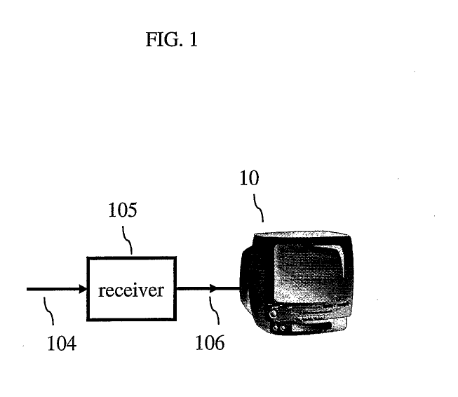

An illustrative portion of a communications system in accordance with the principles of the invention is shown in FIG. 1. As can be observed from FIG. 1, a signal 104 is received by a receiver 105. Signal 104 conveys information representative of control signaling, content (e.g., video), etc. In the context of this example, it is assumed that signal 104 represents a downlink satellite signal after reception by an antenna (not shown). Receiver 105 processes signal 104 in accordance with the principles of the invention (described below) and provides a signal 106 for conveying particular content to a multi-media endpoint as represented by television (TV) 10 for display thereon.

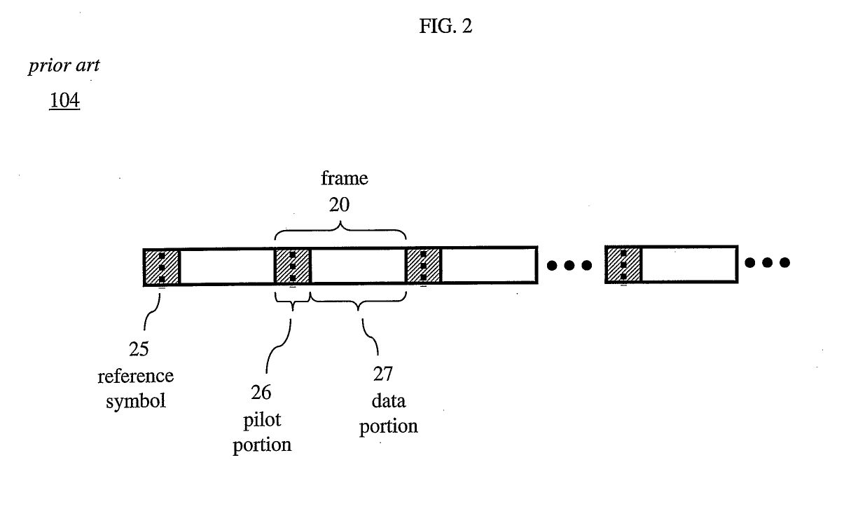

A prior art signal format for signal 104 is shown in FIG. 2. For the purposes of this example, signal 104 comprises a sequence of frames 20, each frame 20 comprising at least a pilot portion 26 and a data portion 27. Pilot portion 26 comprises one, or more, pilot symbols, which are predefined symbols known a priori to receiver 105. If there is more than one pilot symbol in pilot portion 26, it is assumed that at least one of the pilot symbols is predesignated as a reference symbol 25 (described below). It should be noted that the picture of FIG. 2 is not to scale and is merely representative of a signal comprising one or more pilot symbols interspersed with data symbols, which convey other information such as the above-mentioned control signaling and content, as well as, e.g., header and error correction/detection information, etc.

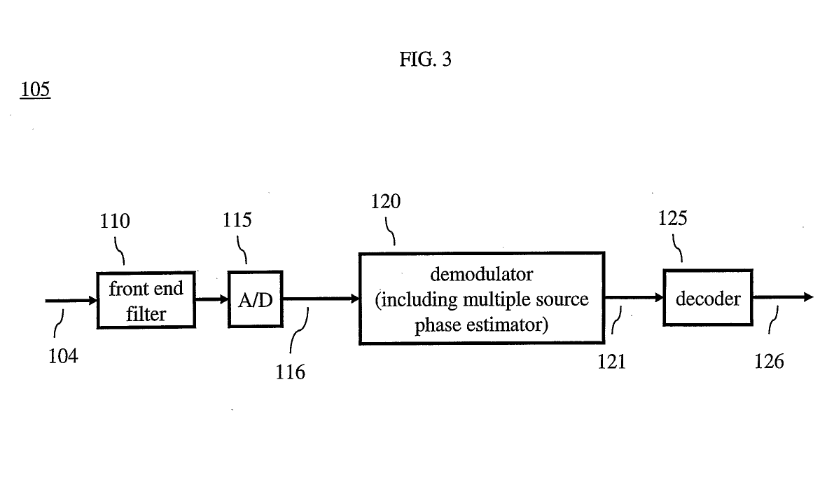

An illustrative portion of receiver 105 in accordance with the principles of the invention is shown in FIG. 3. Receiver 105 includes front end filter 110, analog-to-digital (A/D) converter 115, demodulator 120 and decoder 125. Demodulator 120, in accordance with the principles of the invention, includes at least one multiple source phase estimator (a circuit and/or process) (described below). Front end filter 110 down-converts (e.g., from the satellite transmission bands) and filters received signal 104 to provide a near baseband signal to A/D converter 115, which samples the down converted signal to convert the signal to the digital domain and provide signal 116, which is a sequence of samples, to demodulator 120. The latter performs demodulation of signal 116 (including carrier recovery) and provides a demodulated signal 121 to decoder 125, which decodes the demodulated signal point stream 121 to provide signal 126, which is a bit stream of N bits per symbol interval T. Signal 126 represents the recovered data conveyed on signal 104 of FIG. 1. Data from output signal 126 is eventually provided to TV 10 via signal 106. (In this regard, receiver 105 may additionally process the data before application to TV 10 and/or directly provide the data to TV 10.)

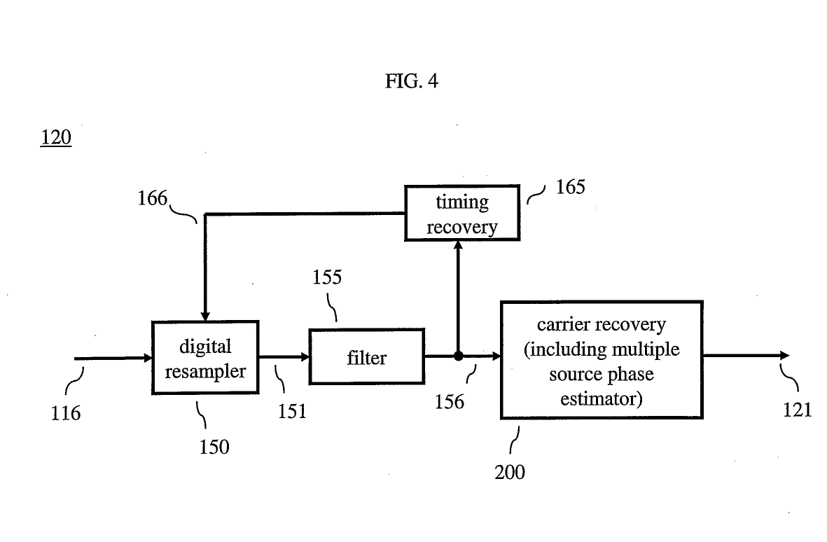

Turning now to FIG. 4, an illustrative block diagram of demodulator 120 in accordance with the principles of the invention is shown. Demodulator 120 includes digital resampler 150, filter 155, carrier recovery element 200, and timing recovery element 165. Signal 116 is applied to digital resampler 150, which resamples signal 116 using timing signal 166, which is provided by timing recovery element 165, to provide resampled signal 151. Resampled signal 151 is applied to filter 155. The latter is a band-pass filter for filtering resampled signal 151 about the carrier frequency to provide a filtered signal 156 to both carrier recovery element 200 and the above-mentioned timing recovery element 165, which generates therefrom timing signal 166. In accordance with the principles of the invention, carrier recovery element 200 includes a multiple source phase estimator for use in derotating, i.e., removing the carrier from, filtered signal 156 to provide a demodulated signal point stream, as represented by signal 121, to decoder 125 of FIG. 3.

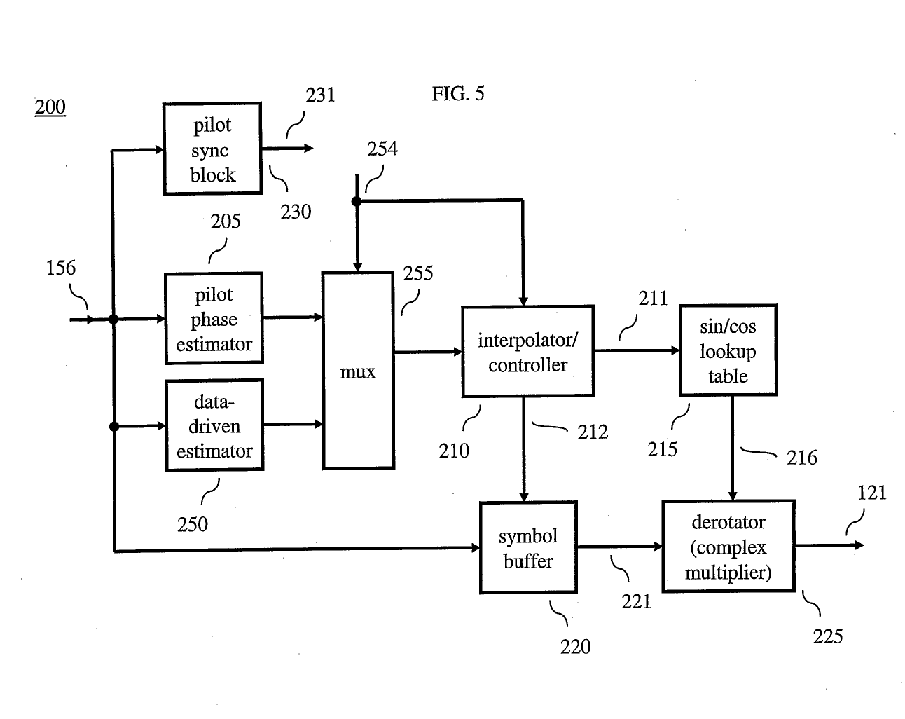

An illustrative embodiment of carrier recovery element 200 is shown in FIG. 5. The elements illustrated in FIG. 5 represent one form of a carrier recovery element that includes a multiple source phase estimator that can be implemented in either hardware and/or software. Carrier recovery element 200 comprises pilot phase estimator 205, a pilot synchronization (sync) block 230, a non-pilot-based phase estimator as illustrated by data-driven estimator 250, multiplexer (mux) 255, interpolator/controller 210, sine/cosine (sin/cos) lookup table 215, symbol buffer 220 and derotator 225 (which is a complex multiplier). Filtered signal 156 is applied to pilot phase estimator 205, pilot sync block 230, symbol buffer 220 and data-driven estimator 250.

Turning first to symbol buffer 220, this buffer collect symbols over a time period (described below), thus providing a time delay to enable calculation of a phase estimate by interpolator/controller 210 before application of a received symbol to derotator 225. In particular, interpolator/controller 210 controls symbol buffer 220, via signal 212, to both synchronize the writing of symbols represented by filtered signal 156 to buffer 220, and the reading of stored symbols from buffer 220 for application to derotator 225 (via signal 221) along with application of the appropriate phase estimate via sin/cos lookup table 215 (via signal 216). It should be noted that other mechanisms can be used to provide the appropriate delay, e.g., a delay line, a first-in-first-out (FIFO) buffer, etc.

Turning next to pilot sync block 230, this block provides a timing signal 231 for use by other elements of FIG. 5 as required. Timing signal 231 provides a time reference with respect to the detection of pilot symbols in filtered signal 156.

Next up is pilot phase estimator 205, this element provides determined phase estimates to mux 255. In particular, upon detection of the one, or more, pilot symbols in filtered signal 156, pilot phase estimator 205 provides a determined phase estimate to mux 255. As noted above, each pilot portion 26 of FIG. 2, or pilot interval, comprises one or more known symbols transmitted at known times. Pilot phase estimator 205 averages the symbols in the pilot intervals to determine an average phase estimate during the pilot interval. For example, if the pilot portion comprises a number of different pilot symbols, an average phase may be determined as illustrated by the equation below:

$$Avg . phase = angle ( {\sum }_{i} {R}_{i} \cdot {P}_{i}^{*} ) , \qquad ( 1 )$$

where Rᵢ are the received pilot symbols, Pᵢ* is the complex conjugate of the known pilot symbols, and the index, i, is over the all the pilot symbols.

This determined phase estimate may be referenced, e.g., to the center symbol (reference symbol) of the pilot interval (as represented by reference symbol 25 of FIG. 2). In other words, the determined phase estimate over the pilot interval is assumed to be the phase 20 at the middle of the pilot interval. Thus, pilot phase estimator 205 provides determined phase estimates at particular times, e.g., every pilot interval, to mux 255.

Likewise, the non-pilot-based phase estimator provides determined phase estimates at particular times, e.g., periodically, to mux 255. In this example, one illustration of a non-pilot-based estimator is provided by data-driven estimator 250. The latter illustratively determines a phase estimate by using a data-driven average, such as represented by the Viterbi and Viterbi algorithm (A. J. Viterbi and A. M. Viterbi, “Nonlinear estimation of PSK-modulated carrier phase with application to burst digital transmission,” IEEE Transactions on Information Theory, vol. IT-29, pp. 543-551, July, 1983). For example, in a quadrature phase-shift keying (QPSK) system, an estimate is made over M symbols of an average phase by adding modified symbols z_{mod} as

$${φ}_{est} = 0.25 {tan}^{- 1} ( {\sum }_{m = 1}^{M} {z}_{mod , m} ) , where \\ {z}_{mod , m} = {\vert {z}_{m} \vert}^{p} exp ( 4 j∠ {z}_{m} ) , \qquad ( 2 )$$

and where the power p is, e.g., equal to 2. It should be noted that, here, the estimate, due to the factor 0.25, is ambiguous beyond plus or minus π/4, rather than plus or minus π.

In view of the above, both pilot phase estimator 205 and data-driven phase estimator 250 provide a sequence of determined phase estimates to mux 255 (also referred to herein as a selector). The latter selects the particular source of determined phase estimates for application to interpolator/controller 210. It should be noted that although in this example only two sources of determined phase estimates are shown, the invention is not so limited and is applicable to any number of sources. Selection of a particular source is performed by signal 254. The latter can either be under software control (e.g., a mode setting, system parameter, etc.) or done via hardware (e.g., a switch). Once a particular source is selected, that sequence of determined phase estimates is provided by mux 255 to interpolator/controller 210. For example, if no pilot is detected in a predetermined amount of time, carrier recovery element 200 defaults to using a non-pilot-based phase estimator source.

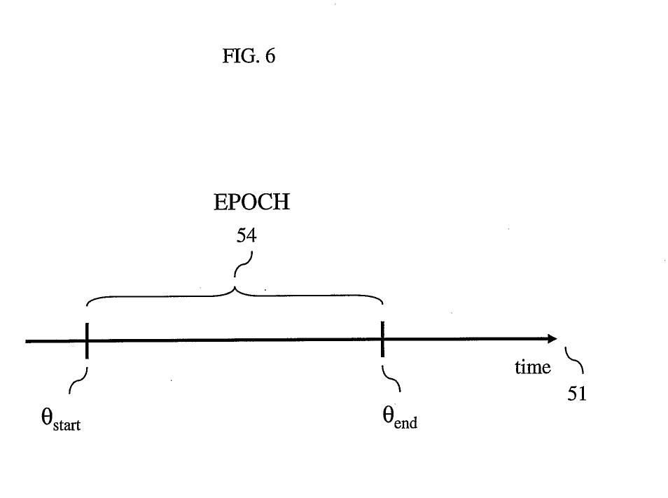

Illustratively, the time between determined phase estimates, whether from pilot phase estimator 205 or data-driven estimator 250, is referred to herein as an “EPOCH.” This is illustrated in FIG. 6 for an illustrative EPOCH 54 spanning a portion of time along time axis 51. The beginning of an EPOCH is marked by the generation of a determined phase estimate, as represented by θₛₜₐᵣₜ in FIG. 6. Likewise, the end of an EPOCH is marked by the generation of a subsequent determined phase estimate, as represented by θ_{end} in FIG. 6. (It should be noted that the end of one EPOCH is the start of another EPOCH, i.e., θ_{end} of one EPOCH is the θₛₜₐᵣₜ for the following EPOCH.) During an EPOCH, N symbols are received and buffered in symbol buffer 220, i.e., the period of time covered by the EPOCH is equal to NT, where T is the symbol interval. (It should be noted that the inventive concept does not require that all EPOCHs have the same time duration.)

Interpolator/controller 210 operates on the sequence of determined phase estimates to provide signal 211 to sin/cos lookup table 215. In accordance with a feature of the invention, it should be noted that interpolator/controller 210 is used whatever the source of determined phase estimates, i.e., interpolator/controller 210 is common, thus minimizing any additional circuitry and/or processing in the receiver. Signal 211 represents a value for the estimated amount of phase needed to derotate a corresponding symbol, i.e., the amount of phase derotation to remove any phase offset. Sin/cos lookup table 215 provides the corresponding sine and cosine values of this phase estimate to complex multiplier 225 for de-rotation of signal 221 to provide down-converted received signal 121.

The estimated phase value represented by signal 211 is referred to herein as φ_{derot}. At the start of an EPOCH, the amount of phase needed to derotate a symbol is φₛₜₐᵣₜ, which is equal to:

φₛₜₐᵣₜ=−θₛₜₐᵣₜ, (3)

where all angles are expressed in radians. As defined herein, φₛₜₐᵣₜ is also referred to herein as the “inverse” of θₛₜₐᵣₜ. At the end of an EPOCH, the amount of phase needed to derotate a symbol is equal to:

φₛₜₐᵣₜ+diffₗᵢₙ. (4)

In this particular example, values for diffₗᵢₙ differ depending on the selected source of determined phase estimates. When pilot phase estimator 205 is selected, diffₗᵢₙ is defined as:

$${diff}_{lin} = \{ \begin{matrix}{φ}_{end} - {φ}_{start} , when - π < {φ}_{end} - {φ}_{start} < π ; \\ {φ}_{end} - {φ}_{start} + 2 π , when {φ}_{end} - {φ}_{start} < - π ; \\ {φ}_{end} - {φ}_{start} - 2 π , when {φ}_{end} - {φ}_{start} > π .\end{matrix} \} \qquad ( 5 )$$

and where φ_{end} is the inverse of θ_{end}, i.e.,

φ_{end}=−θ_{end}, (6)

However, when data-driven estimator 250 is selected, diffₗᵢₙ is defined as:

$${diff}_{lin} = \{ \begin{matrix}{φ}_{end} - {φ}_{start} , when - π / 4 < {φ}_{end} - {φ}_{start} < π / 4 ; \\ {φ}_{end} - {φ}_{start} + π / 2 , when {φ}_{end} - {φ}_{start} < - π / 4 ; \\ {φ}_{end} - {φ}_{start} - π / 2 , when {φ}_{end} - {φ}_{start} > π / 4.\end{matrix} \} . \qquad ( 7 )$$

Equation (7) takes account of the fact that when no pilot symbols are available, and if the Viterbi and Viterbi algorithm is used, the phase estimates of the start phase and end phase may each vary from −π/4 to +π/4. Since, in this example, values for diffₗᵢₙ may vary as a function of the source of determined phase estimates, signal 254 is also applied to interpolator/controller 210 as an indicator of which source is currently selected.

In between the start and end of an EPOCH, the phase required for derotating a received symbol is not known. In order to provide a phase estimate, interpolator/controller 210 performs linear interpolation to generate a value for φ_{derot}. In particular, the above noted value for diffₗᵢₙ is assumed to be linearly distributed over the N symbols of the EPOCH, i.e., for the k^{th} symbol of the EPOCH, the phase estimate, φ_{derot,k} is:

$${φ}_{derot , k} = {φ}_{start} + \frac{k}{N} {diff}_{lin} . \qquad ( 8 )$$

where k represents the symbol index in the EPOCH and N is the total number of symbols within the EPOCH.

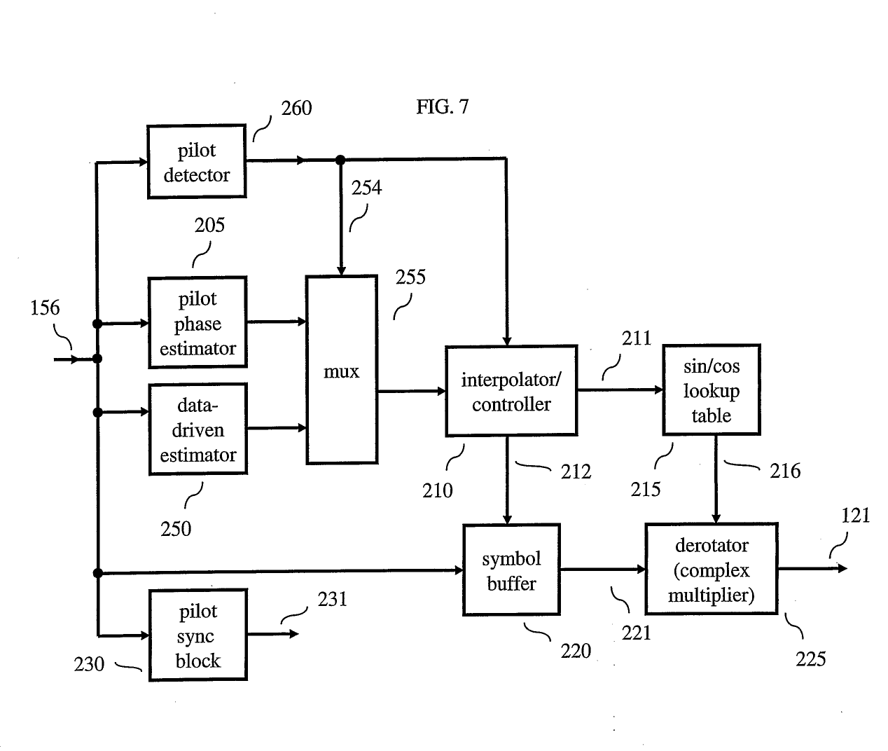

Turning now to FIG. 7, another embodiment in accordance with the principles of the invention is shown. The embodiment of FIG. 7 is similar to the embodiment of FIG. 5 except that signal 254 is provided by pilot detector 260. The latter automatically controls the selection of the source of determined phase estimates. For example, upon detection of the pilot signal, pilot detector 260 controls mux 255, via signal 254, to select pilot phase estimator 205. However, if no pilot signal is detected, e.g., upon expiration of a predetermined amount of time, pilot detector 260 controls mux 255 to select a non-pilot-based phase estimator source (such as represented by data-driven estimator 250). Thus, receiver 105 uses pilot intervals for phase estimates if they exist, uses data-based estimates otherwise, or supplements the pilot-based phase estimates with additional data-based estimates in between.

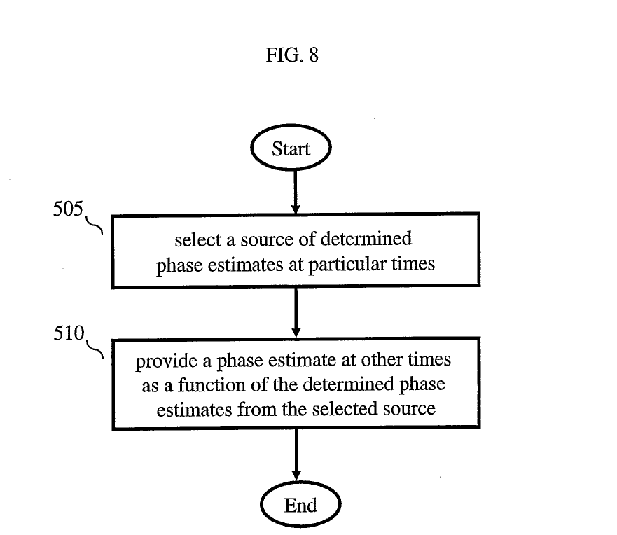

Attention should now be directed to FIG. 8, which shows an illustrative flow chart in accordance with the principles of the invention for use in receiver 105 of FIG. 1. In step 505, receiver 105 selects a source of determined phase estimates at particular times from a number of possible sources. In step 510, receiver 105 provides an estimate of a phase value at other times as a function of the determined phase estimates from the selected source (e.g., using linear interpolation as illustrated by equation (8)). Illustratively, the provided phase estimates are used for derotation of received symbols.

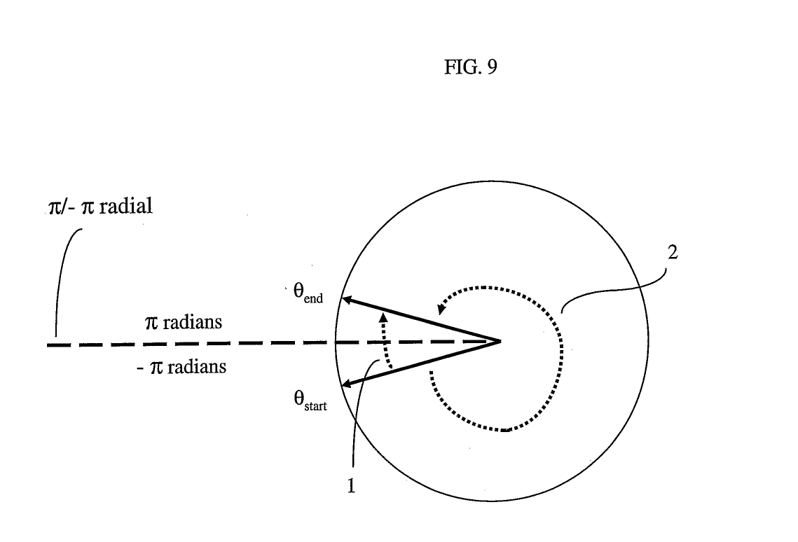

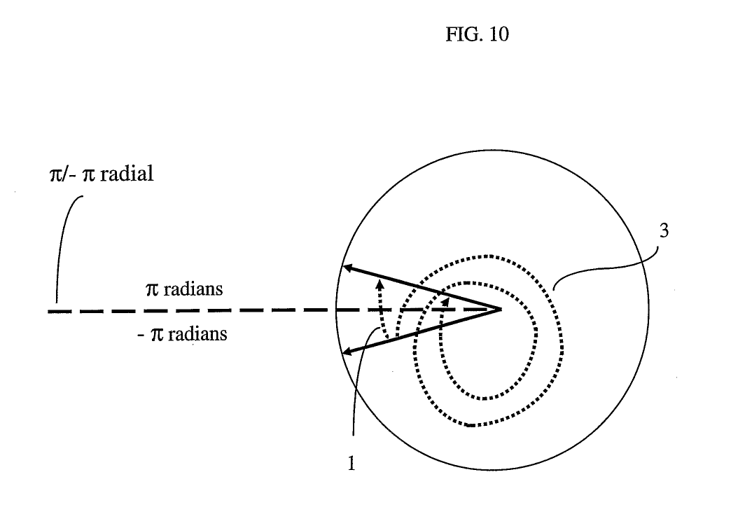

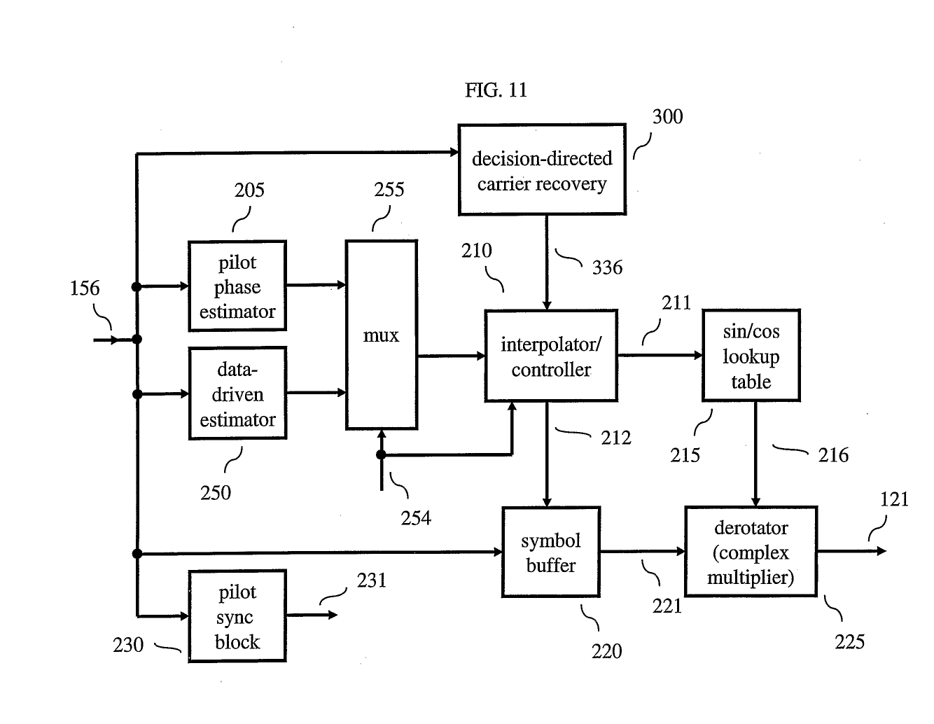

Unfortunately, without knowing how many radians the incoming carrier traversed between the pilot times, the above-described linear interpolation estimate may yield the wrong value for φ_{derot,k}. This is further illustrated in FIGS. 9 and 10. FIG. 9 shows respective values for φₛₜₐᵣₜ and φ_{end} for an illustrative EPOCH. However, as demonstrated by arrows 1 and 2, the starting and ending determined phase estimates do not provide information as to whether the incoming carrier traversed the path represented by arrow 1 or the path represented by arrow 2. Likewise, a similar situation is shown in FIG. 10, which illustrates by the path associated with arrow 3 that the number of radians traversed by the incoming carrier can even be greater than 2π. Therefore, and in accordance with a feature of the invention, decision-directed carrier recovery is used to resolve this ambiguity. This is illustrated in the embodiment of FIG. 11 by the application of filtered signal 156 to decision-directed carrier recovery circuit 300.

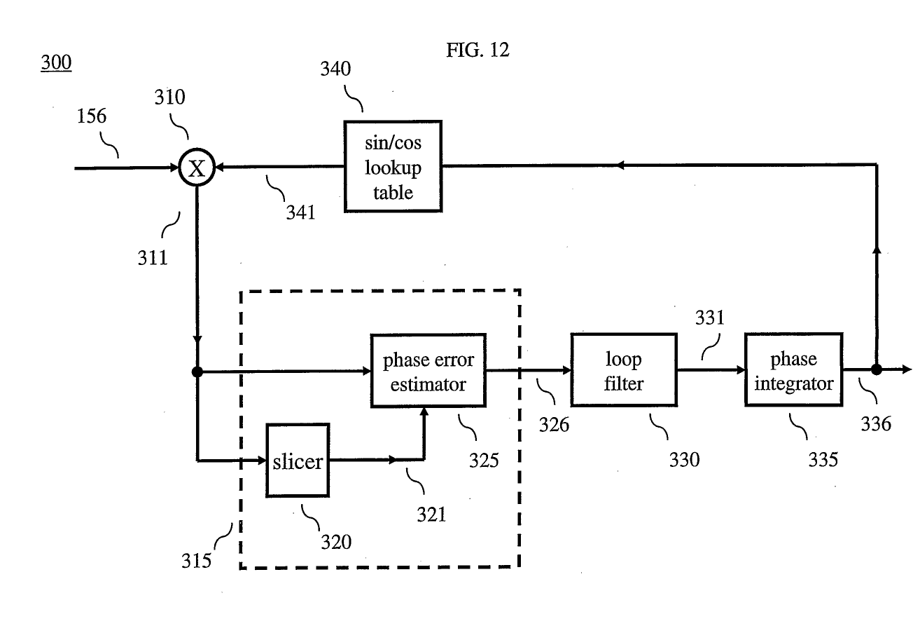

Turning briefly to FIG. 12, an illustrative block diagram for decision-directed carrier recovery circuit 300 is shown. Decision-directed carrier recovery circuit 300 comprises complex multiplier 310, sine/cosine (sin/cos) lookup table 340, phase detector 315, loop filter 330 and phase integrator 335. It is assumed that the processing illustrated by FIG. 12 is in the digital domain (although this is not required), i.e., the carrier recovery circuit 300 includes a digital phase-locked loop (DPLL) driven by hard decisions. Signal 156 is a complex sample stream comprising in-phase (I) and quadrature (Q) components. It should be noted that complex signal paths are not specifically shown in FIG. 12. Complex multiplier 310 receives the complex sample stream of signal 156 and performs de-rotation of the complex sample stream by recovered carrier signal 341. In particular, the in-phase and quadrature components of signal 156 are derotated by a phase of recovered carrier signal 341, which represents particular sine and cosine values provided by sin/cos table 340 (described below). The output signal from complex multiplier 310 is a down-converted received signal 311, e.g., at baseband, and represents a de-rotated complex sample stream of received signal points. The down-converted received signal 311 is applied to phase detector 315, which computes any phase offset still present in the down-converted signal 311 and provides a phase error estimate signal 326 indicative thereof.

As can be observed from FIG. 12, phase detector 315 includes two elements: phase error estimator 325 and slicer 320. As known in the art, the latter makes a hard decision as to the possible symbol (target symbol) represented by the in-phase and quadrature components of each received signal point of down-converted signal 311. In particular, for each received signal point of down-converted signal 311, slicer 320 selects the closest symbol (target symbol) from a predefined constellation of symbols. As such, the phase error estimate signal 326 provided by phase error estimator 325 represents the phase difference between each received signal point and the corresponding target symbol. In particular, phase error estimate signal 326 represents a sequence of phase error estimates, φₑᵣᵣₒᵣ_{_{—}}ₑₛₜᵢₘₐₜₑ, where each particular φₑᵣᵣₒᵣ_{_{—}}ₑₛₜᵢₘₐₜₑ is determined by calculating the imaginary part of the received signal point times the conjugate of the associated sliced symbol, i.e.,

φₑᵣᵣₒᵣ_{_{—}}ₑₛₜᵢₘₐₜₑ=imag(zz_{sliced}*)=|z||z_{sliced}| sin (∠z−∠z_{sliced})≅|z|²(φₑᵣᵣₒᵣ). (9)

In the above equation, Z represents the complex vector of the received signal point, Z_{sliced} represents the complex vector of the associated sliced signal point and Z_{sliced}* represents the conjugate of the complex vector of the associated sliced signal point.

The phase error estimate signal 326 is applied to loop filter 330, which further filters the phase error estimate signal 326 to provide a filtered signal 331. Typically loop filter 330 is a second-order filter comprising proportional and integral paths. Filtered signal 331 is applied to phase integrator 335, which further integrates filtered signal 331 and provides an output phase angle signal 336 to sin/cos lookup table 340. The latter provides the associated sine and cosine values to complex multiplier 310 for de-rotation of signal 156 to provide down-converted received signal 311. Although not shown for simplicity, a frequency offset, F_{OFFSET}, may be fed to loop filter 330, or phase integrator 335, to increase acquisition speed. Also, it should be noted that carrier recovery circuit 300 may operate at multiples of (e.g., twice) the symbol rate of signal 156. As such, phase integrator 335 continues to integrate at all sample times. The output phase angle signal 336 is also applied to interpolator/controller 210 of FIG. 11 to assist in generating a phase estimate. (It should be noted that the output phase angle 336 is already in the form of a derotating phase value and, as such, is the inverse of the signal phase to be corrected.)

Returning now to FIG. 11, the phase of the decision-directed carrier recovery is monitored by interpolator/controller 210 via phase angle signal 336. In particular, interpolator/controller 210 monitors phase angle signal 336 between the start and end of each EPOCH to determine the total phase excursion, diff_{cr}, from beginning to end of an EPOCH, which may exceed π or be less than −π. This total phase excursion, diff_{cr}, is used by interpolator/controller 210 as additional information for use in estimating a value for φ_{derot} for a respective symbol. Although the decision-directed carrier recovery may slightly slip, or be noisy—which is the reason for using an interpolation scheme in the first place—decision-directed carrier recovery should be robust enough for use as an aid to interpolated carrier recovery.

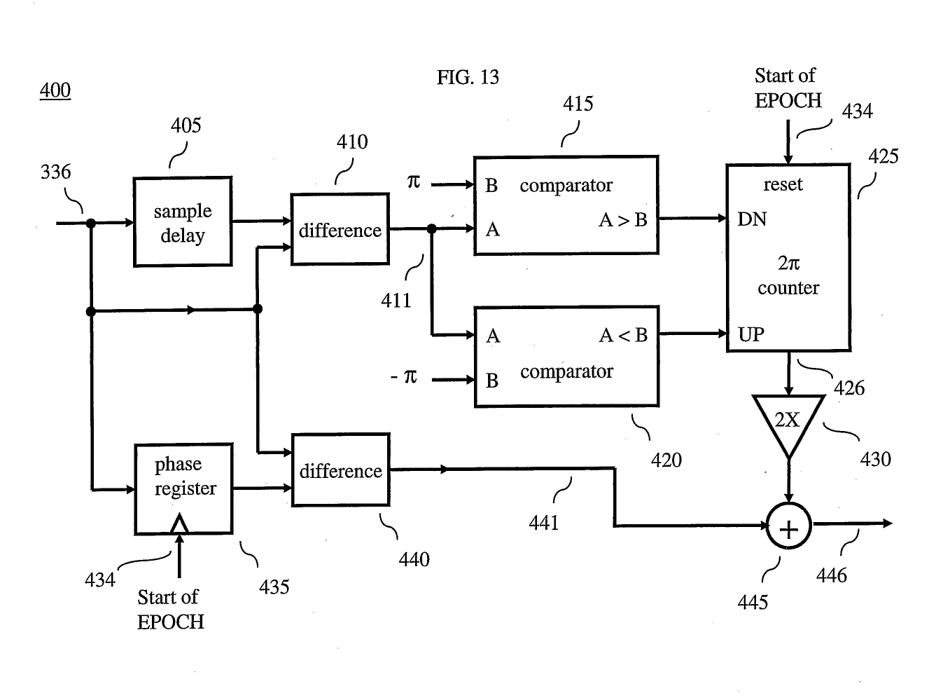

Referring now to FIG. 13, an illustrative phase excursion calculator 400 for use in interpolator/controller 210 for monitoring the total phase excursion diff_{cr} is shown. The elements illustrated in FIG. 13 represent one form of phase excursion calculator that can be implemented in either hardware and/or software. Phase excursion calculator 400 comprises sample delay 405, phase register 435, difference elements 410 and 440, comparators 415 and 420, a counter 425, a multiplier 430 and an adder 445. At the start of an EPOCH (conveyed by signal 434) the value represented by phase angle signal 336 is stored in phase register 435 and counter 425 is reset to a value of zero. Difference element 440 provides a phase difference value 441 between the starting phase value stored in phase register 435 and subsequent phase values during the EPOCH. This phase difference value 441 is also referred to herein as the uncorrected phase difference. The remaining elements of phase excursion calculator 400 track how many times, and in what direction, the value of phase angle signal 336 crosses the π/−π radial (this radial is represented in FIGS. 9 and 10, described earlier). In particular, during an EPOCH, difference element 410 provides a phase difference signal 411, representing sample-to-sample phase difference values by subtracting a previous phase value provided by sample delay element 405 from a current phase value provided by phase angle signal 336. This phase difference value signal is applied to the “A” input leads of comparators 415 and 420. Comparator 415 compares the value of phase difference signal 411 to π (applied to the “B” input lead of comparator 415); while comparator 420 compares the value of phase difference signal 411 to −π (applied to the “B” input lead of comparator 420). If the phase difference value is greater π, then comparator 415 provides a signal from the “A>B” lead of comparator 415 to counter 425. However, if the phase difference value is less than −π, then comparator 420 provides a signal from the “A<B” lead of comparator 420 to counter 425. Counter 425 is, in effect, a 2π counter, i.e., counter 425 counts the number of times and in what direction the π/−π radial is crossed. If the phase difference value is greater than π, then counter 425 is decremented (DN input of counter 425), while if the phase difference value is less than −π, counter 425 is incremented (UP input of counter 425). The output signal 426 from counter 425 is applied to multiplier 430 which multiplies the value represented therein by 2π for addition to the uncorrected phase difference (signal 441) via adder 445 to provide the total phase excursion diff_{cr} (signal 446) for use by interpolator/controller 210. In other words, every time the π/−π radial is crossed in the clockwise direction, the total phase excursion during the EPOCH needs to be decremented by 2π relative to the uncorrected phase difference (signal 441) during the EPOCH. Similarly, every time the π/−π radial is crossed in the counterclockwise direction, the total phase excursion during the EPOCH needs to be incremented by 2π relative to the uncorrected phase difference (signal 441).

As noted above, the beginning and end phases, φₛₜₐᵣₜ and φ_{end}, of the linear interpolation are assumed to be robust from pilot phase estimator 205, and are the inverses of the detected pilot interval phases at the start and end of an EPOCH, respectively. However, the unassisted difference from beginning to end, i.e.,

diffₗᵢₙ=φ_{end}−φₛₜₐᵣₜ, (10)

is assumed, in the absence of additional information, to be off by an integer number, m, of rotations of 2π. The information from the decision-directed carrier recovery is used to select a value for the number m such that the difference interpolated over is within plus or minus π radians of the corrected decision-directed carrier recovery estimate. In particular, the following equations are defined:

diff_{lin,assist}=φ_{end}−φₛₜₐᵣₜ+2mπ; (11)

diff_{cr}−π<diff_{lin,assist}<diff_{cr}+π; and (12)

diff_{cr}−π<φ_{end}−φₛₜₐᵣₜ+2mπ<diff_{cr}+π, (13)

where diff_{lin,assist} is the difference to be used in the linear interpolator (instead of equation (8)), as assisted by decision-directed carrier recovery; and diff_{cr} is the phase difference from beginning to end of an EPOCH as calculated by the decision-directed carrier recovery, corrected for 2π wraps.

From equation (13), the value for m can be found by noting the following:

2mπ<diff_{cr}+π−(φ_{end}−φₛₜₐᵣₜ), or (14)

m<diff_{cf}/(2π)+0.5−(φ_{end}−φₛₜₐᵣₜ)/( 2π), or (15)

m=floor[diff_{cr}/(2π)+0.5−(φ_{end}−φₛₜₐᵣₜ)/( 2π)], (16)

where floor(x) is the largest integer that is less than or equal to x. It should be noted that this floor calculation is easy to perform in the digital domain, as it involves a truncation of bits.

Once m is determined thusly, this value of m is used to determine the value for diff_{lin,assist} from equation (11), above. As such, interpolator/controller 210 provides phase estimates with carrier assist in accordance with the following equation:

$${φ}_{derot , k} = {φ}_{start} + \frac{k}{N} {diff}_{lin , assist ,} . \qquad ( 17 )$$

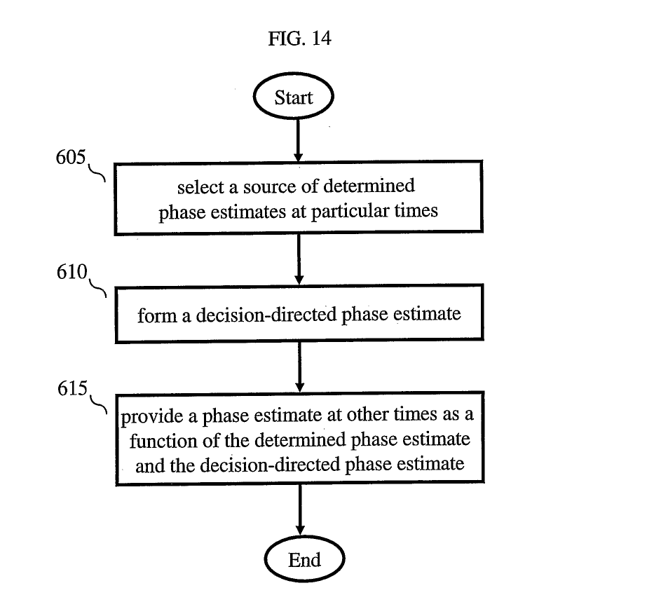

Attention should now be directed to FIG. 14, which shows an illustrative flow chart in accordance with the principles of the invention for use in receiver 105 of FIG. 1. In step 605, receiver 105 selects a source of determined phase estimates at particular times from a number of possible sources. In step 610, receiver 105 forms a decision-directed phase estimate (e.g., using the above-described Costas loop). In step 615, receiver 105 provides an estimate of a phase value at other times as a function of the determined estimate and the decision-directed phase estimate (e.g., using linear interpolation as modified by equation (17)).

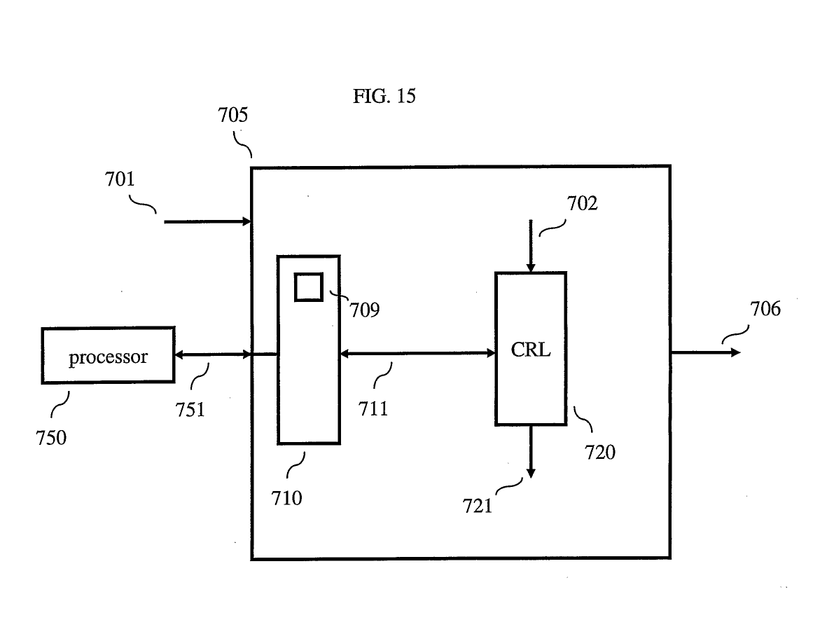

Another illustrative embodiment of the inventive concept is shown in FIG. 15. In this illustrative embodiment an integrated circuit (IC) 705 for use in a receiver (not shown) includes a carrier recovery loop (CRL) 720 and at least one register 710, which is coupled to bus 751. Illustratively, IC 705 is an integrated analog/digital television demodulator/decoder. However, only those portions of IC 705 relevant to the inventive concept are shown. For example, analog-digital converters, filters, decoders, etc., are not shown for simplicity. Bus 751 provides communication to, and from, other components of the receiver as represented by processor 750. Register 710 is representative of one, or more, registers, of IC 705, where each register comprises one, or more, bits as represented by bit 709. The registers, or portions thereof, of IC 705 may be read-only, write-only or read/write. In accordance with the principles of the invention, CRL 720 includes the above-described multiple source phase estimator feature, or operating mode, and at least one bit, e.g., bit 709 of register 710, is a programmable bit that can be set by, e.g., processor 750, for enabling or disabling this operating mode (e.g., to turn-on or turn-off multiple source selection). Likewise, a bit of register 710 may be used to select a particular one of a number of sources of determined phase estimates. In the context of FIG. 3, IC 705 receives an IF signal 701 (e.g., signal 116 of FIG. 3) for processing via an input pin, or lead, of IC 705. A derivative of this signal, 702, is applied to CRL 720 for carrier recovery as described above. CRL 720 provides signal 721, which is a derotated version of signal 702. CRL 720 is coupled to register 710 via internal bus 711, which is representative of other signal paths and/or components of IC 705 for interfacing CRL 720 to register 710 as known in the art. IC 705 provides one, or more, recovered signals, e.g., a composite video signal, as represented by signal 706.

In view of the above, it should be noted that although described in the context of a satellite communications system, the inventive concept is not so limited. For example, the elements of FIG. 1 may represent other types of systems and other forms of multi-media endpoints. For example, satellite radio, terrestrial broadcast, cable TV, etc. Also, although described herein in the context of a single demodulator, it should be realized that the inventive concept is applicable to multi-modulation receivers, where information may be conveyed on different signal layers. For example, layered modulation receivers, hierarchical modulation receivers, or combinations thereof. Indeed, the invention is applicable to any type of receiver in which carrier recovery is performed. Finally, it should be noted that the embodiments described above may operate at the symbol rate or some other rate, for example, samples at twice the symbol rate. This is so other processing, e.g., a fractionally-spaced equalizer, may be also be used in the receiver.

As such, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements may be embodied on one or more integrated circuits (ICs). Similarly, although shown as separate elements, any or all of the elements may be implemented in a stored-program-controlled processor, e.g., a digital signal processor (DSP) or microprocessor that executes associated software, e.g., corresponding to one or more of the elements shown in FIG. 5, etc. Further, although shown as separate elements, the elements therein may be distributed in different units in any combination thereof. For example, receiver 105 may be a part of TV 10 or receiver 105 may be located further upstream in a distribution system, e.g., at a head-end, which then retransmits the content to other nodes and/or receivers of a network. It is therefore to be understood that numerous modifications may be made to the illustrative embodiments and that other arrangements may be devised without departing from the spirit and scope of the present invention as defined by the appended claims.

1. A receiver comprising:
a pilot-based phase estimator;
a non-pilot-based phase estimator; and
a selector for selecting between the pilot-based phase estimator and the non-pilot-based phase estimator as a source of determined phase estimates for use in performing carrier recovery on a received signal.

2. The receiver of claim 1, wherein the non-pilot-based phase estimator is a data-driven average estimator.

3. The receiver of claim 2, wherein the data-driven average estimator is based on the Viterbi and Viterbi algorithm.

4. The receiver of claim 1, further comprising an interpolator, wherein the interpolator provides interpolated phase estimates over an interval of time and wherein the interpolator performs linear interpolation based on a respective determined phase estimate.

5. The receiver of claim 1, further comprising an interpolator and a decision-directed phase estimator, wherein the interpolator provides interpolated phase estimates over an interval of time and wherein the interpolator performs linear interpolation based on a respective determined phase estimate and at least one decision-directed phase error estimate from the decision-directed phase estimator.

6. The receiver of claim 1, wherein the selector selects the non-pilot-based phase estimator upon expiration of a time interval if no pilot is detected in the received signal.

7. A receiver comprising:
a demodulator for demodulating a received signal; and
a decoder for decoding the demodulated received signal to provide a decoded signal;
wherein the demodulator includes a multiple source phase estimator for demodulating the received signal comprising
a pilot-based phase estimator;
a non-pilot-based phase estimator;
a selector for selecting between the pilot-based phase estimator and the non-pilot-based phase estimator as a source of determined phase estimates for the received signal at particular times;
an interpolator for providing interpolated phase estimates at other times, wherein the interpolator performs linear interpolation based on a respective determined phase estimate; and
a derotator for providing the demodulated received signal, wherein the derotator derotates symbols of the received signal in accordance with the interpolated phase estimates.

8. The receiver of claim 7, wherein the selector selects the non-pilot-based phase estimator upon expiration of a time interval if no pilot is detected in the received signal.

9. The receiver of claim 7, wherein the non-pilot-based phase estimator is a data-driven average estimator.

10. The receiver of claim 9, wherein the data-driven average estimator is based on the Viterbi and Viterbi algorithm.

11. A receiver comprising:
a demodulator for demodulating a received signal; and
a decoder for decoding the demodulated received signal to provide a decoded signal;
wherein the demodulator includes a multiple source phase estimator for demodulating the received signal comprising
a pilot-based phase estimator;
a non-pilot-based phase estimator;
a selector for selecting between the pilot-based phase estimator and the non-pilot-based phase estimator as a source of determined phase estimates for the received signal at particular times;
a decision-directed phase estimator;
an interpolator for providing interpolated phase estimates at other times, wherein the interpolator performs linear interpolation based on a respective determined phase estimate and at least one decision-directed phase error estimate from the decision-directed phase estimator; and
a derotator for providing the demodulated received signal, wherein the derotator derotates symbols of the received signal in accordance with the interpolated-phase estimates.

12. The receiver of claim 11, wherein the selector selects the non-pilot-based phase estimator upon expiration of a time interval if no pilot is detected in the received signal.

13. The receiver of claim 11, wherein the non-pilot-based phase estimator is a data-driven average estimator.

14. The receiver of claim 13, wherein the data-driven average estimator is based on the Viterbi and Viterbi algorithm.

15. A receiver comprising:
a carrier recovery element for use in demodulating a received signal; and
a register, wherein the register sets one of a number of modes for the carrier recovery element, and wherein one of the number of modes is a pilot-based phase estimator mode and another of the number of modes is a non-pilot-based phase estimator mode.

16. A method for use in a receiver, the method comprising:
selecting one of a number of sources for provided determined phase estimates of a received signal; and
providing interpolated phase estimates of the received signal using determined phase estimates from the selected source.

17. The method of claim 16, wherein one of the number of sources is a pilot-based phase estimator and another one of the number of sources is a non-pilot-based phase estimator.

18. The method of claim 17, wherein the selecting step includes the step of selecting the non-pilot-based phase estimator upon expiration of a time interval if no pilot is detected in the received signal.

19. The method of claim 17, wherein the non-pilot-based phase estimator is a data-driven average estimator.

20. The method of claim 19, wherein the data-driven average estimator is based on the Viterbi and Viterbi algorithm.

21. The method of claim 16, wherein the providing step includes the steps of:
providing decision-directed phase estimates of the received signal; and
interpolating the phase estimates of the received signal using the determined phase estimates from the selected source and at least one of the provided decision-directed phase estimates.

22. A method for use in a receiver, the method comprising:
demodulating a received signal using a multiple source phase estimator; and
decoding the demodulated received signal to provide a decoded signal;
and wherein the demodulating step includes the steps of:
selecting between a pilot-based phase estimator and a non-pilot-based phase estimator as a source of determined phase estimates for the received signal at particular times;
providing interpolated phase estimates at other times, wherein the interpolation is a form of linear interpolation based on a respective determined phase estimate; and
derotating symbols of the received signal in accordance with the interpolated phase estimates to provide the demodulated received signal.

23. The method of claim 22, wherein the selecting step includes the step of selecting the non-pilot-based phase estimator upon expiration of a time interval if no pilot is detected in the received signal.

24. The method of claim 23, wherein the non-pilot-based phase estimator is a data-driven average estimator.

25. The method of claim 24, wherein the data-driven average estimator is based on the Viterbi and Viterbi algorithm.

26. A method for use in a receiver, the method comprising:
demodulating a received signal using a multiple source phase estimator; and
decoding the demodulated received signal to provide a decoded signal;
and wherein the demodulating step includes the steps of:
selecting between a pilot-based phase estimator and a non-pilot-based phase estimator as a source of determined phase estimates for the received signal at particular times;
providing decision-directed phase estimates of the received signal;
providing interpolated phase estimates at other times, wherein the interpolation is a form of linear interpolation based on a respective determined phase estimate and at least one of the decision-directed phase error estimates; and
derotating symbols of the received signal in accordance with the interpolated phase estimates to provide the demodulated received signal.

27. The method of claim 26, wherein the selecting step includes the step of selecting the non-pilot-based phase estimator upon expiration of a time interval if no pilot is detected in the received signal.

28. The method of claim 27, wherein the non-pilot-based phase estimator is a data-driven average estimator.

29. The method of claim 28, wherein the data-driven average estimator is based on the Viterbi and Viterbi algorithm.

30. A method for use in a receiver, the method comprising:
using a register to set one of a number of modes for a carrier recovery element; and
using the carrier recovery element in the set mode for demodulating a received signal;
wherein one of the number of modes is a pilot-based phase estimator mode and another of the number of modes is a non-pilot-based phase estimator mode.
